(19) United States
(12) Patent Application Publication
(10) Pub. No.: US 2025/0226181 A1
(43) Pub. Date: Jul. 10, 2025

(54) PLASMA PROCESSING APPARATUS AND POWER SUPPLY SYSTEM

(71) Applicant: Tokyo Electron Limited, Tokyo (JP)

(72) Inventors: Mitsuhiro IWANO, Miyagi (JP); Motoki NORO, Miyagi (JP)

(73) Assignee: Tokyo Electron Limited, Tokyo (JP)

(21) Appl. No.: 19/091,933

(22) Filed: Mar. 27, 2025

Related U.S. Application Data
(63) Continuation of application No. PCT/JP2023/032784, filed on Sep. 8, 2023.

(30) Foreign Application Priority Data
Sep. 29, 2022 (JP) 2022-157036

(51) Int. Cl. H01J 37/32

(52) U.S. Cl. CPC H01J 37/32174; H01J 37/32091; H01J 37/32146; H01J 2237/334

(57) ABSTRACT

A technique for improving controllability of plasma generated on a substrate is provided. A plasma processing apparatus includes a chamber, a substrate support disposed inside the chamber and including a lower electrode, an upper electrode disposed above the substrate support, a first RF power supply for supplying a first RF signal having a first RF frequency to the upper electrode or the lower electrode, a second RF power supply for suppling a second RF signal having a second RF frequency to the lower electrode, and a third RF power supply for supplying a third RF signal having a third RF frequency to the lower electrode. The three RF power supplies supply RF signals having respective power levels in three periods in each cycle.

### CROSS-REFERENCE TO RELATED APPLICATIONS

This application is a bypass continuation application of international application No. PCT/JP2023/032784 having an international filing date of Sep. 8, 2023 and designating the United States, the international application being based upon and claiming the benefit of priority from Japanese Patent Application No. 2022-157036, filed on Sep. 29, 2022, the entire contents of each are incorporated herein by reference.

### TECHNICAL FIELD

Exemplary embodiments of the present disclosure relate to a plasma processing apparatus and a power supply system.

### BACKGROUND

As a technique for controlling ions in plasma in an etching process, there is a plasma etching method described in US2017/0125260.

### CITATION LIST

### Patent Documents

Patent Literature 1: US2017/0125260.

### SUMMARY

The present disclosure provides a technique for improving controllability of plasma generated on a substrate.

A plasma processing apparatus according to an exemplary embodiment of the present disclosure includes a chamber, a substrate support disposed inside the chamber and including a lower electrode, an upper electrode disposed above the substrate support, a first RF power supply configured to supply a first RF signal having a first RF frequency to the upper electrode or the lower electrode, the first RF signal having a first power level in a first period in each cycle, having a second power level in a second period after the first period in each cycle, and having a third power level in a third period after the second period in each cycle, the third power level having a zero power level, a second RF power supply configured to supply a second RF signal having a second RF frequency to the lower electrode, the second RF signal having a fourth power level in the first period in each cycle, having a fifth power level in the second period in each cycle, and having a sixth power level in the third period in each cycle, the fourth power level and the sixth power level having a zero power level, and a third RF power supply configured to supply a third RF signal having a third RF frequency to the lower electrode, the third RF signal having a seventh power level in the first period in each cycle, having an eighth power level in the second period in each cycle, and having a ninth power level in the third period in each cycle, the seventh power level and the eighth power level having a zero power level.

According to one or more embodiments of the present disclosure, a technique for improving controllability of plasma generated on a substrate can be provided.

### BRIEF DESCRIPTION OF DRAWINGS

FIG. 1 is a diagram illustrating an example of a configuration of a plasma processing system.

FIG. 2 is a diagram illustrating an example of a configuration of a capacitively coupled plasma processing apparatus.

FIG. 3 is a view illustrating a configuration of a plasma processing apparatus according to a first exemplary mode.

FIG. 4 is a view illustrating an example of supply of a first RF signal, a second RF signal, and a third RF signal.

FIG. 5 is a view illustrating an example of a relationship between the three types of RF signals, and ion energy (Ei) and ion flux (Flux) of ions in plasma on a substrate.

FIG. 6 is a view illustrating an example of a behavior of ions in plasma in a first period, a second period, and a third period.

FIG. 7 is a view illustrating an example of the supply of the first RF signal, the second RF signal, and the third RF signal.

FIG. 8 is a view illustrating an example of the supply of the first RF signal, the second RF signal, and the third RF signal.

FIG. 9 is a view illustrating an example of a variation of the ion energy (Ei) and the ion flux (Flux) in the first period, the second period, and the third period.

FIG. 10 is a view illustrating a configuration of a plasma processing apparatus using a voltage pulse signal in one or more embodiments.

FIG. 11 is a view illustrating an example of supply of the first RF signal and the second RF signal, and application of the voltage pulse signal.

FIG. 12 is a view illustrating a configuration of a plasma processing apparatus according to a second exemplary mode.

FIG. 13 is a view illustrating an example of the supply of the first RF signal and the second RF signal.

FIG. 14 is a view illustrating an example of a relationship between the two types of RF signals, and the ion energy (Ei) and the ion flux (Flux) of ions in the plasma on the substrate.

FIG. 15 is a view illustrating an example of the supply of the first RF signal and the second RF signal.

FIG. 16 is a view illustrating an example of the supply of the first RF signal and the second RF signal.

FIG. 17 is a view illustrating an example of the supply of the first RF signal and the second RF signal.

FIG. 18 is a view illustrating a configuration of a plasma processing apparatus using a voltage pulse signal in one or more embodiments.

FIG. 19 is a view illustrating an example of supply of the first RF signal and the application of the voltage pulse signal.

### DETAILED DESCRIPTION

An embodiment of the present disclosure will be described below.

In one or more embodiments, there is provided a plasma processing apparatus including a chamber, a substrate support disposed inside the chamber and including a lower electrode, an upper electrode disposed above the substrate support, a first RF power supply configured to supply a first RF signal having a first RF frequency to the upper electrode or the lower electrode, the first RF signal having a first power level in a first period in each cycle, having a second power level in a second period after the first period in each cycle, and having a third power level in a third period after the second period in each cycle, the third power level having a zero power level, a second RF power supply configured to supply a second RF signal having a second RF frequency to the lower electrode, the second RF signal having a fourth power level in the first period in each cycle, having a fifth power level in the second period in each cycle, and having a sixth power level in the third period in each cycle, the fourth power level and the sixth power level having a zero power level, and a third RF power supply configured to supply a third RF signal having a third RF frequency to the lower electrode, the third RF signal having a seventh power level in the first period in each cycle, having an eighth power level in the second period in each cycle, and having a ninth power level in the third period in each cycle, the seventh power level and the eighth power level having a zero power level.

In one or more embodiments, the first power level is larger than the second power level.

In one or more embodiments, the second power level has a zero power level.

In one or more embodiments, the first RF frequency is larger than the second RF frequency, and the second RF frequency is larger than the third RF frequency.

In one or more embodiments, the third RF frequency is within a range of 300 kHz to 600 kHz.

In one or more embodiments, there is provided a plasma processing apparatus including a chamber, a substrate support disposed inside the chamber and including a lower electrode, an upper electrode disposed above the substrate support, a first RF power supply configured to supply a first RF signal having a first RF frequency to the upper electrode or the lower electrode, the first RF signal having a first power level in a first period in each cycle, having a second power level in a second period after the first period in each cycle, and having a third power level in a third period after the second period in each cycle, the third power level having a zero power level, a second RF power supply configured to supply a second RF signal having a second RF frequency to the lower electrode, the second RF signal having a fourth power level in the first period in each cycle, having a fifth power level in the second period in each cycle, and having a sixth power level in the third period in each cycle, the fourth power level and the sixth power level having a zero power level, and a voltage pulse generator configured to apply a voltage pulse signal to the lower electrode, the voltage pulse signal having a voltage pulse sequence that has a first voltage level in the first period and the second period in each cycle and has a second voltage level in the third period in each cycle, an absolute value of the second voltage level being larger than an absolute value of the first voltage level.

In one or more embodiments, the first power level is larger than the second power level.

In one or more embodiments, the second power level has a zero power level.

In one or more embodiments, the second voltage level has a negative polarity.

In one or more embodiments, the first voltage level has a zero voltage level.

In one or more embodiments, the voltage pulse sequence has a pulse frequency within a range of 300 kHz to 600 kHz.

In one or more embodiments, there is provided a plasma processing apparatus including a chamber, a substrate support disposed inside the chamber and including a lower electrode, an upper electrode disposed above the substrate support, a first RF power supply configured to supply a first RF signal having a first RF frequency to the upper electrode or the lower electrode, the first RF frequency having a MHz band, the first RF signal having a first power level in a first period in each cycle, having a second power level in a second period after the first period in each cycle, and having a third power level in a third period after the second period in each cycle, the second power level being smaller than the first power level, the third power level having a zero power level, and a second RF power supply configured to supply a second RF signal having a second RF frequency to the lower electrode, the second RF frequency having a kHz band, the second RF signal having a fourth power level in the first period in each cycle, having a fifth power level in the second period in each cycle, and having a sixth power level in the third period in each cycle, the fourth power level having a zero power level, the sixth power level being larger than the fifth power level.

In one or more embodiments, the second power level has a zero power level.

In one or more embodiments, the second RF frequency is within a range of 300 kHz to 600 kHz.

In one or more embodiments, there is provided a plasma processing apparatus including a chamber, a substrate support disposed inside the chamber and including a lower electrode, an upper electrode disposed above the substrate support, an RF power supply configured to supply an RF signal to the upper electrode or the lower electrode, the RF signal having a first power level in a first period in each cycle, having a second power level in a second period after the first period in each cycle, and having a third power level in a third period after the second period in each cycle, the second power level being smaller than the first power level, the third power level having a zero power level, and a voltage pulse generator configured to apply a voltage pulse signal to the lower electrode, the voltage pulse signal having a voltage pulse sequence that has a first voltage level in the third period in each cycle.

In one or more embodiments, the voltage pulse signal has a voltage pulse sequence that has a second voltage level in the second period in each cycle, and an absolute value of the first voltage level is larger than an absolute value of the second voltage level.

In one or more embodiments, there is provided a power supply system used in a plasma processing apparatus, the power supply system including a first RF generator configured to generate a first RF signal having a first RF frequency, the first RF signal having a first power level in a first period in each cycle, having a second power level in a second period after the first period in each cycle, and having a third power level in a third period after the second period in each cycle, the third power level having a zero power level, a second RF generator configured to generate a second RF signal having a second RF frequency, the second RF signal having a fourth power level in the first period in each cycle, having a fifth power level in the second period in each cycle, and having a sixth power level in the third period in each cycle, the fourth power level and the sixth power level having a zero power level, and a third RF generator configured to generate a third RF signal having a third RF frequency, the third RF signal having a seventh power level in the first period in each cycle, having an eighth power level in the second period in each cycle, and having a ninth power level in the third period in each cycle, the seventh power level and the eighth power level having a zero power level.

In one or more embodiments, there is provided a power supply system used in a plasma processing apparatus, the power supply system including a first RF generator configured to generate a first RF signal having a first RF frequency, the first RF signal having a first power level in a first period in each cycle, having a second power level in a second period after the first period in each cycle, and having a third power level in a third period after the second period in each cycle, the third power level having a zero power level, a second RF generator configured to generate a second RF signal having a second RF frequency, the second RF signal having a fourth power level in the first period in each cycle, having a fifth power level in the second period in each cycle, and having a sixth power level in the third period in each cycle, the fourth power level and the sixth power level having a zero power level, and a voltage pulse generator configured to generate a voltage pulse signal, the voltage pulse signal having a voltage pulse sequence that has a first voltage level in the first period and the second period in each cycle and has a second voltage level in the third period in each cycle, an absolute value of the second voltage level being larger than an absolute value of the first voltage level.

In one or more embodiments, there is provided a power supply system used in a plasma processing apparatus, the power supply system including a first RF generator configured to generate a first RF signal having a first RF frequency, the first RF frequency having a MHz band, the first RF signal having a first power level in a first period in each cycle, having a second power level in a second period after the first period in each cycle, and having a third power level in a third period after the second period in each cycle, the second power level being smaller than the first power level, the third power level having a zero power level, and a second RF generator configured to generate a second RF signal having a second RF frequency, the second RF frequency having a kHz band, the second RF signal having a fourth power level in the first period in each cycle, having a fifth power level in the second period in each cycle, and having a sixth power level in the third period in each cycle, the fourth power level having a zero power level, the sixth power level being larger than the fifth power level.

In one or more embodiments, there is provided a power supply system used in a plasma processing apparatus, the power supply system including an RF generator configured to generate an RF signal, the RF signal having a first power level in a first period in each cycle, having a second power level in a second period after the first period in each cycle, and having a third power level in a third period after the second period in each cycle, the second power level being smaller than the first power level, the third power level having a zero power level, and a voltage pulse generator configured to generate a voltage pulse signal, the voltage pulse signal having a voltage pulse sequence that has a first voltage level in the third period in each cycle.

Hereinafter, each embodiment of the present disclosure will be described in detail with reference to the drawings. In the drawings, the same or similar elements have the same reference characters, and duplicated descriptions thereof will be omitted. Unless otherwise specified, the upward-downward positional relationship, the rightward/leftward positional relationship, and other positional relationship will be described based on the positional relationships shown in the drawings. The dimensional ratios in the drawings do not indicate actual ratios, and the actual ratios are not limited to the illustrated ratios.

### Example of Plasma Processing System

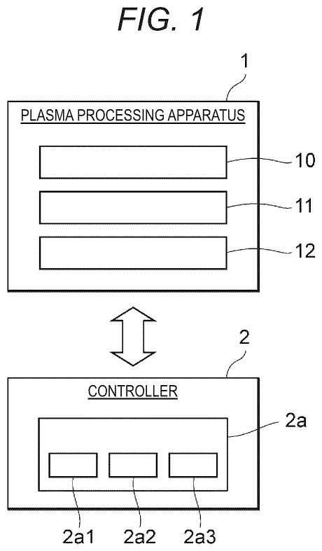

FIG. 1 is a diagram illustrating an example of a configuration of a plasma processing system. In one or more embodiments, the plasma processing system includes a plasma processing apparatus 1 and a controller 2. The plasma processing system is an example of a substrate processing system, and the plasma processing apparatus 1 is an example of the substrate processing apparatus. The plasma processing apparatus 1 includes a plasma processing chamber (also simply referred to as “chamber”) 10, a substrate support 11, and a plasma generator 12. The plasma processing chamber 10 has a plasma processing space. The plasma processing chamber 10 has at least one gas supply port via which at least one processing gas is supplied into the plasma processing space, and at least one gas exhaust port via which the gas is exhausted from the plasma processing space. The gas supply port is connected to a gas supply 20, which will be described later, and the gas exhaust port is connected to an exhaust system 40, which will be described later. The substrate support 11 is disposed in the plasma processing space and has a substrate support surface for supporting a substrate.

The plasma generator 12 is configured to generate a plasma from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. Furthermore, various types of plasma generators, including an alternating current (AC) plasma generator and a direct current (DC) plasma generator, may be used. In one or more embodiments, an AC signal (AC power) used by the AC plasma generator has a frequency within a range from 100 kHz to 10 GHz. The AC signal therefore includes a radio frequency (RF) signal and a microwave signal. In one or more embodiments, the RF signal has a frequency within a range from 100 kHz to 150 MHz.

The controller 2 processes computer-executable instructions that cause the plasma processing apparatus 1 to execute various steps described in the present disclosure. The controller 2 may be configured to control elements of the plasma processing apparatus 1 to execute the various steps described herein below. In one or more embodiments, part or all of the controller 2 may be in the plasma processing apparatus 1. The controller 2 may include a processor 2a1, a storage 2a2, and a communication interface 2a3. The controller 2 is implemented, for example, by a computer 2a. The processor 2a1 may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2a1, and executed thereby. The medium may be any of various recording media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASICA.

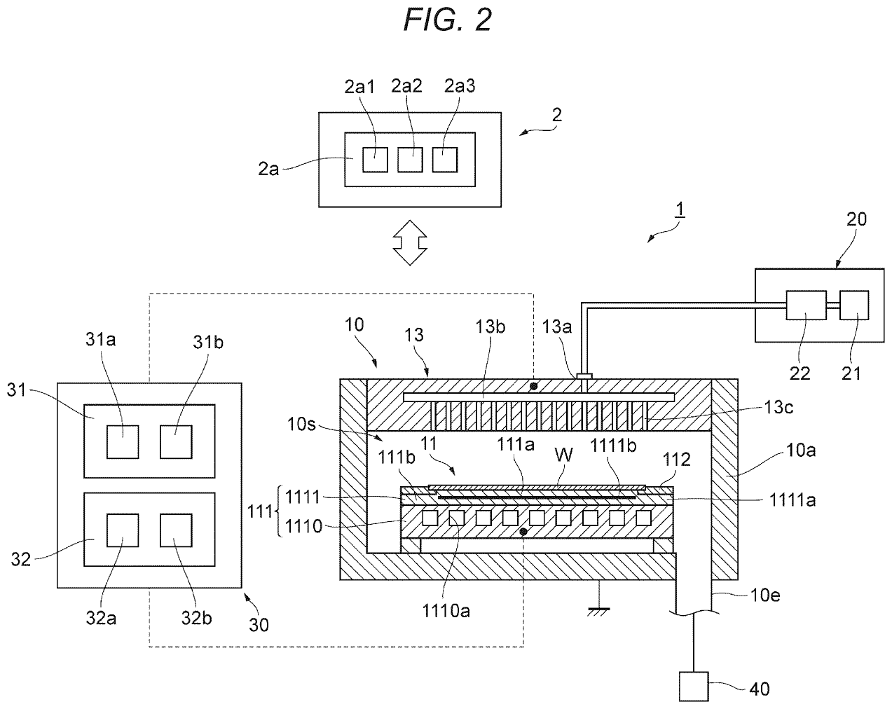

Hereinafter, an example of a configuration of a capacitively-coupled plasma processing apparatus as an example of the plasma processing apparatus 1 will be described. FIG. 2 is a diagram illustrating the example of the configuration of the capacitively-coupled plasma processing apparatus.

The capacitively-coupled plasma processing apparatus 1 includes the plasma processing chamber 10, the gas supply 20, a power supply system 30, and the exhaust system 40. The plasma processing apparatus 1 includes the substrate support 11 and a gas introduction unit. The gas introduction unit is configured to introduce at least one processing gas into the plasma processing chamber 10. The gas introduction unit includes a showerhead 13. The substrate support 11 is disposed in the plasma processing chamber 10. The showerhead 13 is disposed above the substrate support 11. In one or more embodiments, the showerhead 13 constitutes at least a portion of a ceiling of the plasma processing chamber 10. The plasma processing chamber 10 has a plasma processing space 10s defined by the showerhead 13, a sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a main body 111 and a ring assembly 112. The main body 111 has a central region 111a, which supports a substrate W, and an annular region 111b, which supports the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. Accordingly, the central region 111a is also called a substrate support surface that supports the substrate W, and the annular region 111b is also called a ring support surface that supports the ring assembly 112.

In one or more embodiments, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a, and an electrostatic electrode 1111b disposed in the ceramic member 1111a. The ceramic member 1111a has the central region 111a. In one or more embodiments, the ceramic member 1111a also has the annular region 111b. Another member that surrounds the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. At least one RF/DC electrode coupled to an RF power supply 31 and/or a DC power supply 32, which will be described later, may be disposed in the ceramic member 1111a. In this case, at least one RF/DC electrode functions as the lower electrode. When a bias RF signal and/or DC signal, which will be described later, are supplied to the at least one RF/DC electrode, the RF/DC electrode is also called a bias electrode. The conductive member of the base 1110 and at least one RF/DC electrode may function as a plurality of lower electrodes.

The ring assembly 112 includes one or more annular members. In one or more embodiments, the one or more annular members include one or more edge rings and at least one cover ring. The edge ring is made of an electrically conductive material or an insulating material, and the cover ring is made of an insulating material.

The substrate support 11 may further include a temperature control module configured to adjust a temperature of at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one or more embodiments, the flow path 1110a is formed in the base 1110, and one or more heaters are disposed in the ceramic member 1111a of the electrostatic chuck 1111. The substrate support 11 may further include a heat transfer gas supply configured to supply a heat transfer gas to a gap between a rear surface of the substrate W and the central region 111a.

The showerhead 13 is configured to introduce at least one processing gas from the gas supply 20 into the plasma processing space 10s. The showerhead 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. The showerhead 13 further includes at least one upper electrode. The gas introduction unit may include, in addition to the showerhead 13, one or a plurality of side gas injectors (SGI) that are attached to one or a plurality of openings formed in the sidewall 10a.

The gas supply 20 may include at least one gas source 21 and at least one flow controller 22. In one or more embodiments, the gas supply 20 is configured to supply at least one processing gas from the respective corresponding gas sources 21 to the showerhead 13 via the respective corresponding flow controllers 22. The flow controller 22 may include, for example, a mass flow controller or a pressure-controlled flow controller. Further, the gas supply 20 may include at least one flow modulation device that modulates or pulses a flow rate of at least one processing gas.

The power supply system 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. A plasma is thus generated from the at least one processing gas supplied into the plasma processing space 10s. Accordingly, the RF power supply 31 may function as at least a part of the plasma generator 12. Supplying the bias RF signal to at least one lower electrode can generate a bias potential in the substrate W to attract an ionic component in the formed plasma to the substrate W.

In one or more embodiments, the RF power supply 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In one or more embodiments, the source RF signal has a frequency within a range from 10 MHz to 150 MHz. In one or more embodiments, the first RF generator 31a may be configured to generate a plurality of source RF signals having different frequencies. The generated one or more source RF signals are supplied to at least one lower electrode and/or at least one upper electrode.

The second RF generator 31b is coupled to the at least one lower electrode via the at least one impedance matching circuit and configured to generate the bias RF signal (bias RF power). A frequency of the bias RF signal may be the same as or different from a frequency of the source RF signal. In one or more embodiments, the bias RF signal has a frequency lower than the frequency of the source RF signal. In one or more embodiments, the bias RF signal has a frequency within a range from 100 kHz to 60 MHz. In one or more embodiments, the second RF generator 31b may be configured to generate a plurality of bias RF signals having different frequencies. The generated one or more bias RF signals are supplied to at least one lower electrode. In various embodiments, at least one of the source RF signal and the bias RF signal may be pulsed.

Further, the power supply system 30 may include a DC power supply 32 coupled to the plasma processing chamber 10. The DC power supply 32 includes a first DC generator 32a and a second DC generator 32b. In one or more embodiments, the first DC generator 32a is connected to at least one lower electrode to generate a first DC signal. The generated first DC signal is applied to at least one lower electrode. In one or more embodiments, the second DC generator 32b is connected to at least one upper electrode and configured to generate a second DC signal. The generated second DC signal is applied to the at least one upper electrode.

In various embodiments, the first and second DC signals may be pulsed. In this case, a sequence of voltage pulses is applied to at least one lower electrode and/or at least one upper electrode. The voltage pulses may each have a rectangular, trapezoidal, or triangular pulse waveform or a combination thereof. In one or more embodiments, a waveform generator that generates the sequence of the voltage pulses from a DC signal is connected between the first DC generator 32a and at least one lower electrode. Accordingly, the first DC generator 32a and the waveform generator form a voltage pulse generator. When the second DC generator 32b and the waveform generator form a voltage pulse generator, the voltage pulse generator is connected to at least one upper electrode. The voltage pulse may have a positive polarity or a negative polarity. The sequence of the voltage pulses may include one or more positive voltage pulses and one or more negative voltage pulses in one cycle. The first DC generator 32a and the second DC generator 32b may be provided in addition to the RF power supply 31, or the first DC generator 32a may be provided in place of the second RF generator 31b.

The exhaust system 40 may be connected, for example, to a gas exhaust port 10e disposed at a bottom of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

### First Aspect

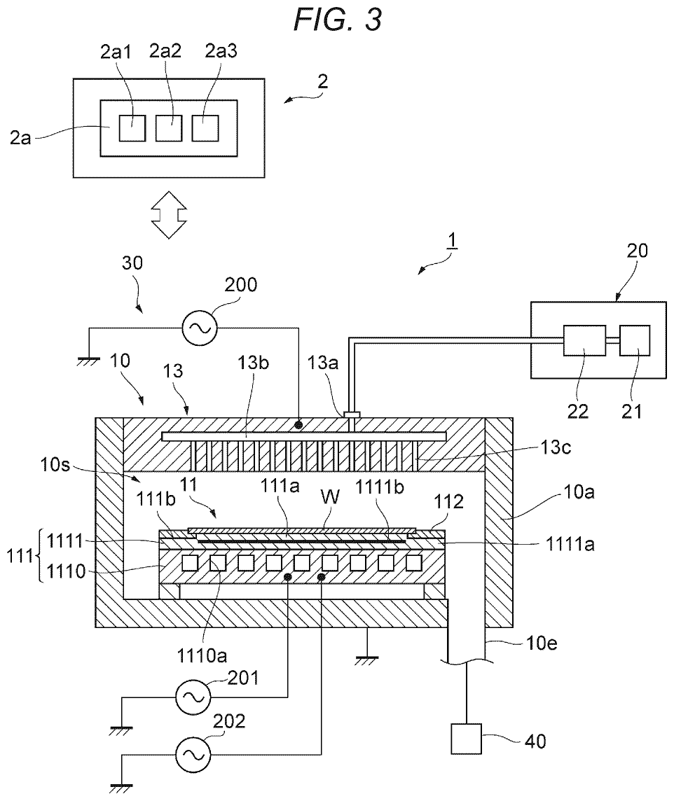

As illustrated in FIG. 3, the plasma processing apparatus 1 may include the power supply system 30 that supplies RF signals having three different RF frequencies to the upper electrode or the lower electrode. In one or more embodiments, the power supply system 30 may include a first RF power supply 200, a second RF power supply 201, and a third RF power supply 202. That is, the power supply system 30 is also referred to as an RF system.

In one or more embodiments, the first RF power supply 200 is electrically connected to the upper electrode and configured to generate a first RF signal. The generated first RF signal is supplied to the upper electrode. The first RF power supply 200 may include a first RF generator. In one or more embodiments, the first RF signal has a frequency in a MHz band. In one or more embodiments, the first RF signal has a frequency within a range of 40 MHz to 150 MHz. In one or more embodiments, the first RF signal may have a frequency within a range of 80 MHz to 120 MHz.

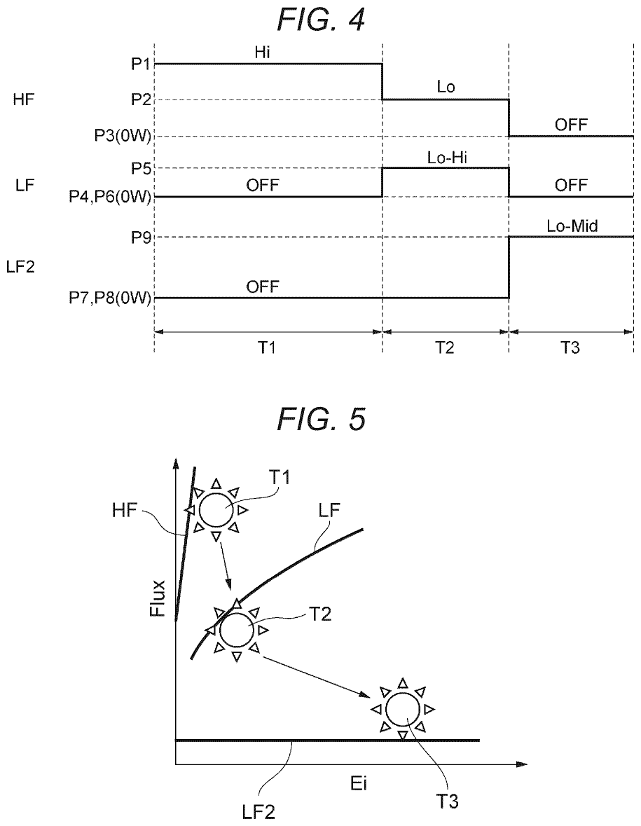

As shown in FIG. 4, a plurality of cycles are executed at a repetition frequency of 0.1 kHz to 50 kHz during plasma processing, and each cycle has a first period T1, a second period T2, and a third period T3 in this order. In one or more embodiments, one cycle having the first period T1, the second period T2, and the third period T3 is set a plurality of times for the plasma processing of each substrate W. The second period T2 and the third period T3 may be shorter than the first period T1. Lengths of the second period T2 and the third period T3 may be the same or different from each other.

In one or more embodiments, the first RF signal (HF) has a first power level P1 in the first period T1 in each cycle, a second power level P2 in the second period T2 in each cycle, and a third power level P3 in the third period T3 in each cycle. In one or more embodiments, the first power level P1 is larger than the second power level P2. The third power level P3 may be a zero power level, and the third period T3 may be in a state in which the first RF signal (HF) is not supplied to the upper electrode (OFF state). The second power level P2 may be larger than the third power level P3, and the second period T2 may be in a state in which the first RF signal (HF) is supplied to the upper electrode (ON state).

In one or more embodiments, as illustrated in FIG. 3, the second RF power supply 201 is electrically connected to the lower electrode and configured to generate a second RF signal. The generated second RF signal is supplied to the lower electrode. The second RF power supply 201 may include a second RF generator. In one or more embodiments, the second RF signal has a frequency in the MHz band. In one or more embodiments, the second RF signal has a frequency lower than the frequency of the first RF signal (HF). In one or more embodiments, the second RF signal has a frequency within a range of 1 MHz to 80 MHz. In one or more embodiments, the second RF signal may have a frequency within a range of 10 MHz to 60 MHz.

In one or more embodiments, as illustrated in FIG. 4, the second RF signal (LF) has a fourth power level P4 in the first period T1 in each cycle, has a fifth power level P5 in the second period T2 in each cycle, and has a sixth power level P6 in the third period T3 in each cycle. In one or more embodiments, the fourth power level P4 and the sixth power level P6 may be a zero power level, and the first period T1 and the third period T3 may be in a state in which the second RF signal (LF) is not supplied to the lower electrode (OFF state). The fifth power level P5 may be larger than the fourth power level P4 and the sixth power level P6, and the second period T2 may be in a state in which the second RF signal (LF) is supplied to the lower electrode (ON state).

In one or more embodiments, as illustrated in FIG. 3, the third RF power supply 202 is electrically connected to the lower electrode and configured to generate a third RF signal. The generated third RF signal is supplied to the lower electrode. The third RF power supply 202 may include a third RF generator. In one or more embodiments, the third RF signal has a frequency lower than the first RF signal (HF) and the second RF signal (LF). In one or more embodiments, the third RF signal has a frequency in a kHz band. In one or more embodiments, the third RF signal has a frequency within a range of 100 kHz to 1000 kHz. In one or more embodiments, the third RF signal may have a frequency within a range of 300 kHz to 600 kHz.

In one or more embodiments, as illustrated in FIG. 4, the third RF signal (LF2) has a seventh power level P7 in the first period T1 in each cycle, has an eighth power level P8 in the second period T2 in each cycle, and has a ninth power level P9 in the third period T3 in each cycle. In one or more embodiments, the seventh power level P7 and the eighth power level P8 may be a zero power level, and the first period T1 and the second period T2 may be in a state in which the third RF signal (LF2) is not supplied to the lower electrode (OFF state). The ninth power level P9 may be larger than the seventh power level P7 and the eighth power level P8, and the third period T3 may be a state in which the third RF signal (LF2) is supplied to the lower electrode (ON state).

### Example of Plasma Processing

The plasma processing performed using the plasma processing apparatus 1 includes an etching process of etching a film on the substrate W using plasma. In one or more embodiments, the plasma processing is executed by the controller 2.

First, the substrate W is transported (i.e., moved) into the plasma processing chamber 10 by a transporting arm, placed on the substrate support 11 by a lifter, and suctioned and held by the substrate support 11 as illustrated in FIG. 3.

The processing gas is then supplied to the showerhead 13 by the gas supply 20, and is supplied from the showerhead 13 to the plasma processing space 10s. The processing gas supplied at this point in time includes a gas that generates an active species required to etch the substrate W.

In one or more embodiments, the first RF signal (HF) is supplied to the upper electrode by the first RF power supply 200. The second RF signal (LF) and the third RF signal (LF2) are supplied to the lower electrode by the second RF power supply 201 and the third RF power supply 202. In this case, an atmosphere in the plasma processing space 10s may be exhausted from the gas exhaust port 10e, and the pressure in the plasma processing space 10s may be reduced to a given pressure. As a result, plasma is generated in the plasma processing space 10s, and the substrate W is etched.

In one or more embodiments, as illustrated in FIG. 4, in the first period T1 in the plasma processing, the first RF signal (HF) having the first power level P1 is supplied to the upper electrode (ON state). In one or more embodiments, the first power level P1 has a high power level (High). The second RF signal (LF) and the third RF signal (LF2) are not supplied to the lower electrode (OFF state).

FIG. 5 is a view illustrating an example of a relationship between the three types of RF signals and ion energy (Ei) and ion flux (Flux) of ions in the plasma on the substrate W. The ion flux (Flux) correlates with an amount of ions generated in the plasma generated on the substrate W, and the ion energy (Ei) correlates with a force (perpendicularity of the ions to a substrate surface when ions enter the substrate surface) that attracts the ions onto the substrate W. As illustrated in FIG. 5, the supply of the first RF signal (HF) having a high frequency contributes to the variation of the ion flux (Flux) of ions present in the plasma. When the power level of the first RF signal (HF) is raised, the ion flux increases. Meanwhile, the ion energy (Ei) does not vary significantly by the supply of the first RF signal (HF). The supply of the second RF signal (LF) having a medium frequency contributes to the variation of both the ion energy and the ion flux. The supply of the third RF signal (LF2) having a low frequency contributes to the variation of the ion energy. Meanwhile, the supply of the third RF signal (LF2) contributes almost nothing to the variation of the ion flux. By combining and using the three types of RF signals, the ion energy (Ei) and the ion flux (Flux) of the plasma on the substrate W can be controlled.

Since only the first RF signal (HF) is supplied in the first period T1 in one or more embodiments, the ion flux is high and the ion energy is low on the substrate W in the plasma processing space 10s.

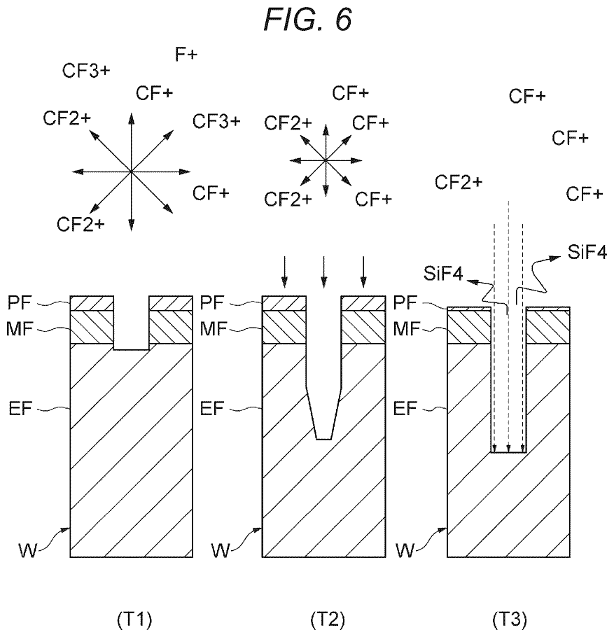

FIG. 6 is a view illustrating an example of a behavior of the ions in plasma in the first period T1, the second period T2, and the third period T3. As shown in FIG. 6, in one or more embodiments, in the first period T1, ions and radicals caused from the CF-containing gas that is the processing gas are generated in a large amount and diffused, and a part thereof is adsorbed to a mask film MF on the surface of the substrate W, so that a protective film PF is formed.

While the example illustrated in FIG. 6 is an example in which the CF-containing gas is used as the processing gas, the type of the processing gas is not particularly limited, and the processing gas may include, for example, at least one type selected from the group consisting of a fluorine-containing gas, an oxygen-containing gas, and a halogen-containing gas. Further, while the example illustrated in FIG. 6 is an example in which a silicon oxide film is used as an etching film, the type of the etching film or the mask film is not particularly limited, and the etching film or the mask film may include, for example, at least one type selected from the group consisting of a silicon-containing film, a carbon-containing film, and a metal-containing film.

In the second period T2 in the plasma processing, the first RF signal (HF) having the second power level P2 is supplied to the upper electrode, and the second RF signal (LF) having the fifth power level P5 is supplied to the lower electrode (ON state), as illustrated in FIG. 4. The third RF signal (LF2) is not supplied to the lower electrode (OFF state). In one or more embodiments, the second power level P2 has a power level (Low) lower than the first power level P1.

In the second period T2, as illustrated in FIG. 5, the ion flux decreases and the ion energy slightly increases on the substrate W in the plasma processing space 10s as compared with the first period T1. As a result, as illustrated in FIG. 6, in the second period T2, the generation of ions and radicals is suppressed, and the ions are attracted toward the substrate W. As a result, an etching film EF is etched while the protective film PF is formed. The larger the fifth power level P5 is, the more the formation of the protective film PF is promoted, and the smaller the fifth power level P5 is, the more the etching of the etching film EF is promoted.

In the third period T3 in the plasma processing, the first RF signal (HF) is not supplied to the upper electrode (OFF state), the second RF signal (LF) is not supplied to the lower electrode (OFF state), and the third RF signal (LF2) having the ninth power level P9 is supplied to the lower electrode (ON state), as illustrated in FIG. 4.

In the third period T3, as illustrated in FIG. 5, the ion flux decreases and the ion energy increases on the substrate W in the plasma processing space 10s as compared with the second period T2. That is, the ion flux is low, and the ion energy is high. As a result, as illustrated in FIG. 6, in the third period T3, the ions are strongly attracted toward the substrate W, and the etching film EF is etched. In this case, the ions are attracted perpendicularly to the substrate W, the ions reach the bottom of the hole of the etching film EF, and a hole diameter of the bottom is secured. Further, the corners of the mask film MF is suppressed from being scraped obliquely or a sidewall of the mask film MF or the etching film EF is suppressed from being bulged.

According to the present exemplary embodiment, the plasma processing apparatus 1 includes the first RF power supply 200 that supplies the first RF signal (HF) to the upper electrode, the second RF power supply 201 that supplies the second RF signal (LF) to the lower electrode, and the third RF power supply 202 that supplies the third RF signal (LF2) to the lower electrode. The first RF signal (HF) has the first power level P1 in the first period T1 in each cycle, the second power level P2 in the second period T2 in each cycle, and the third power level P3 having a zero power level in the third period T3 in each cycle. The second RF signal (LF) has the fourth power level P4 having a zero power level in the first period T1 in each cycle, has the fifth power level P5 in the second period T2 in each cycle, and has the sixth power level P6 having a zero power level in the third period T3 in each cycle. The third RF signal (LF2) has the seventh power level P7 having a zero power level in the first period T1 in each cycle, has the eighth power level P8 having a zero power level in the second period T2 in each cycle, and has the ninth power level P9 in the third period T3 in each cycle. Accordingly, since the RF signals of the three frequencies can be supplied at a given power level in the respective periods T1 to T3 in each cycle, the ion energy and the ion flux of the generated plasma can be independently controlled. As a result, it is possible to improve the controllability of the plasma generated on the substrate.

According to the present exemplary embodiment, by supplying only the first RF signal (HF) having a high frequency in the first period T1 in each cycle, it is possible to promote the formation of the protective film on the film on the substrate W, while suppressing the etching with respect to the film on the substrate W, in a state where the ion flux is high and the ion energy is low. In the second period T2 in each cycle, by supplying the second RF signal (LF) having a medium frequency, both the ion flux and the ion energy are ensured, the ions are attracted and the film on the substrate W can be etched while a stronger protective film is formed on the film on the substrate W. As a result, the etching of the etching film can be progressed while the expansion of an opening hole of the mask film is suppressed. Further, by adjusting the power level of the RF signal in the second period T2, the balance between a forming action and the etching action of the protective film by ions can be adjusted. When the third RF signal (LF2) having a low frequency is supplied in the third period T3 in each cycle, the ion flux is low and the ion energy is high, so that the attraction of ions can be strongly performed. As a result, it is possible to increase the perpendicularity of the ions with respect to the substrate W and promote the etching of the etching film. As a result, it is possible to suppress the diameter of the bottom of the hole formed in the etching film from being small, the width of the hole of the etching film from being partially narrowed, or the corners of the mask film from being scraped obliquely. Accordingly, an etching shape is improved.

### Other Examples of First Aspect

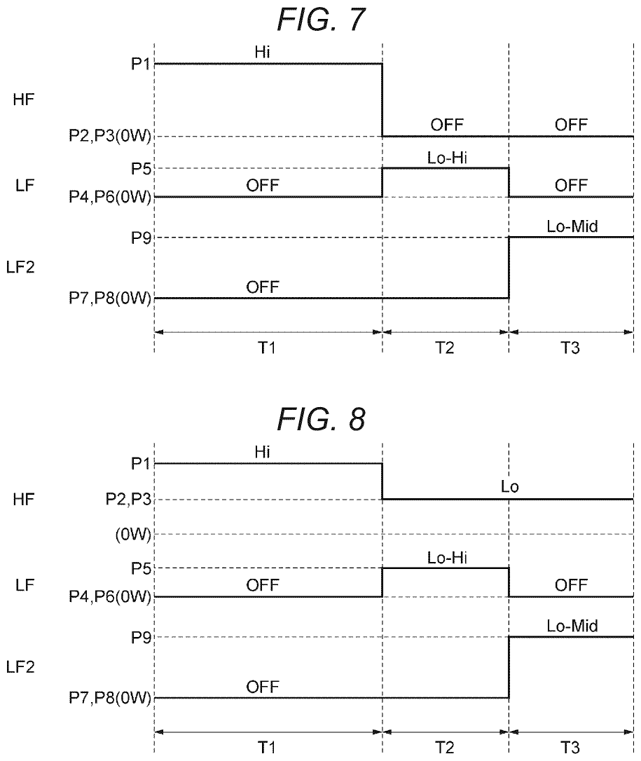

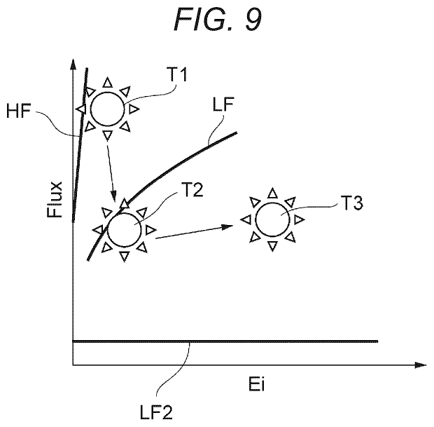

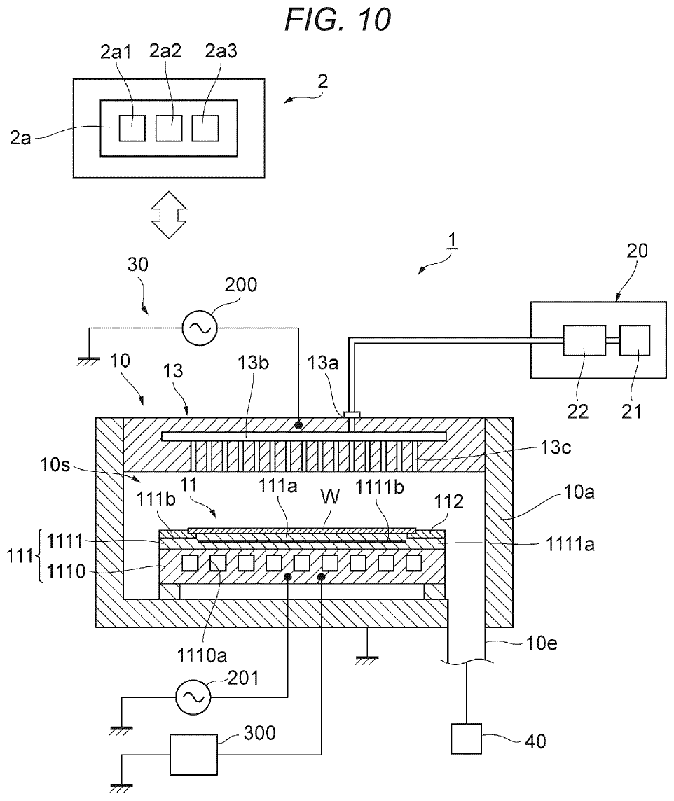

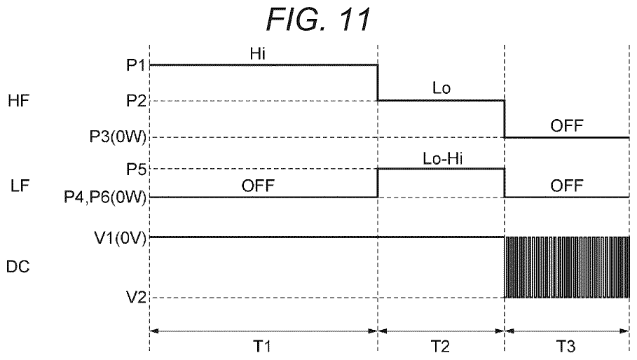

In the first aspect, as illustrated in FIG. 7, the second power level P2 of the first RF signal (HF) may be a zero power level in the second period T2 in each cycle. In this case, in the second period T2, the ion flux of the plasma on the substrate W decreases, so that the forming action of the protective film by ions is relatively weak, and the etching action is relatively strong.

In the first aspect, as illustrated in FIG. 8, in the third period T3 in each cycle, the third power level P3 of the first RF signal (HF) may be larger than a zero power level, and the first RF signal (HF) may be supplied to the upper electrode (ON state). In one or more embodiments, the third power level P3 may be the same power level (Low) as the second power level P2. As shown in FIG. 9, in the third period T3, the ion flux of the plasma on the substrate increases, so that the forming action of the protective film is improved.

In the first aspect, the first period T1, the second period T2, and the third period T3 in each cycle may be consecutively performed, or there may be a period (OFF period), in which the first RF signal (HF), the second RF signal (LF), and the third RF signal (LF2) are all stopped, between the first period T1 and the second period T2, and between the second period T2 and the third period T3. The first RF signal (HF) may be supplied to the lower electrode, instead of the upper electrode.

In the first aspect described above, as illustrated in FIG. 10, the plasma processing apparatus 1 may include a voltage pulse generator 300 instead of the third RF power supply 202. That is, instead of the third RF signal (LF2), a voltage pulse signal may be applied to the lower electrode. Other components of the plasma processing apparatus 1 may be similar to those in the above-described aspect.

The voltage pulse generator 300 is electrically connected to the lower electrode and configured to generate a voltage pulse signal. The generated voltage pulse signal is applied to the lower electrode. As illustrated in FIG. 11, in one or more embodiments, the voltage pulse signal (DC) may have a voltage pulse sequence that has a first voltage level V1 in the first period T1 and the second period T2 in each cycle and has a second voltage level V2 in the third period T3 in each cycle.

In one or more embodiments, the first voltage level V1 has a zero voltage level. In one or more embodiments, the voltage pulse sequence has a pulse frequency within a range of 300 kHz to 600 kHz. An absolute value of the second voltage level V2 may be larger than an absolute value of the first voltage level V1. In one or more embodiments, the second voltage level V2 has a negative polarity. The supply and power levels of the first RF signal (HF) and the second RF signal (LF) may be the same as those in the first aspect illustrated in FIG. 4.

Since the voltage pulse signal (DC) is applied in the third period T3 in one or more embodiments, the ion energy increases on the substrate W in the plasma processing space 10s than in the first period T1 and the second period T2. As a result, in the third period T3, the ions are strongly attracted toward the substrate W, and the etching film EF is etched. In this case, the ions are attracted perpendicularly to the substrate W, the ions reach the bottom of the hole of the etching film EF, and the hole diameter of the bottom is secured. Further, the corners of the mask film MF is suppressed from being scraped obliquely or the sidewall of the mask film MF or the etching film EF is suppressed from being bulged. The present mode in which the voltage pulse signal (DC) is applied by the voltage pulse generator 300 may be applied to all the first aspects shown in FIGS. 7 and 8 and the like.

### Second Aspect

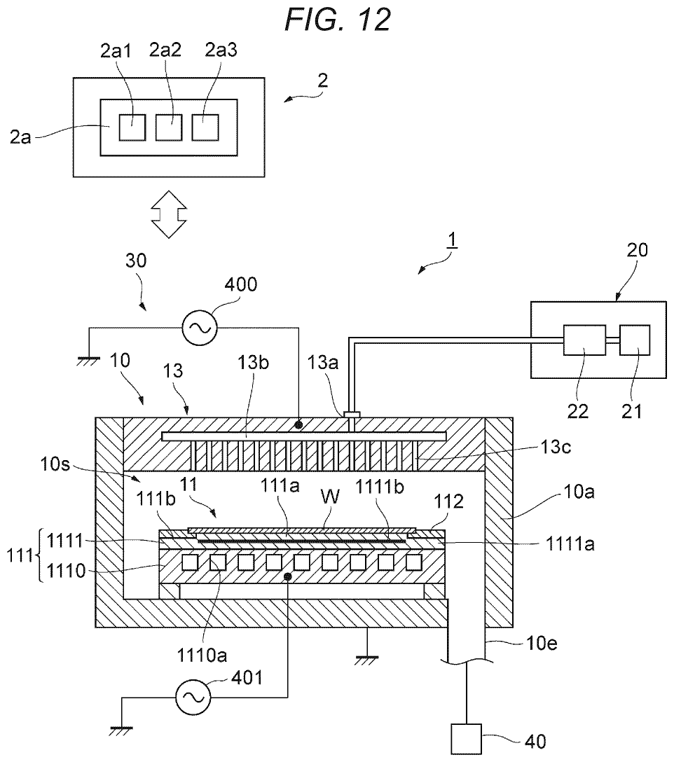

As shown in FIG. 12, the plasma processing apparatus 1 may include the power supply system 30 that supplies an RF signal having an RF frequency in the MHz band and an RF signal having an RF frequency in the kHz band to the upper electrode or the lower electrode. In one or more embodiments, the power supply system 30 may include a first RF power supply 400 and a second RF power supply 401.

In one or more embodiments, the first RF power supply 400 is electrically connected to the upper electrode and configured to generate a first RF signal (MHz-band RF signal). The generated first RF signal is supplied to the upper electrode. In one or more embodiments, the first RF signal has a frequency within a range of 40 MHz to 150 MHz. In one or more embodiments, the first RF signal may have a frequency within a range of 80 MHz to 120 MHz.

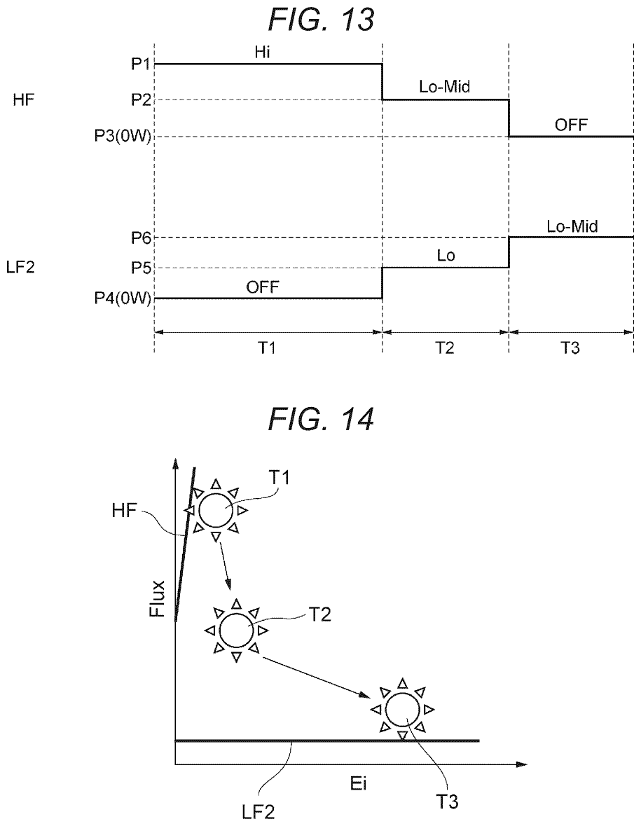

As illustrated in FIG. 13, a plurality of cycles are performed at a repetition frequency of 0.1 kHz to 50 kHz during the plasma processing, and each cycle has the first period T1, the second period T2, and the third period T3 in this order. In one or more embodiments, one cycle having the first period T1, the second period T2, and the third period T3 is set a plurality of times for the plasma processing of each substrate W. The second period T2 and the third period T3 may be shorter than the first period T1. Lengths of the second period T2 and the third period T3 may be the same or different from each other.

In one or more embodiments, the first RF signal (HF) has the first power level P1 in the first period T1 in each cycle, the second power level P2 in the second period T2 in each cycle, and the third power level P3 in the third period T3 in each cycle. In one or more embodiments, the first power level P1 is larger than the second power level P2. The third power level P3 may be a zero power level, and the third period T3 may be in a state in which the first RF signal (HF) is not supplied to the upper electrode (OFF state). The second power level P2 may be larger than the third power level P3, and the second period T2 may be in a state in which the first RF signal (HF) is supplied to the upper electrode (ON state).

In one or more embodiments, as illustrated in FIG. 12, the second RF power supply 401 is electrically connected to the lower electrode and configured to generate a second RF signal (kHz band RF signal). The generated second RF signal is supplied to the lower electrode. In one or more embodiments, the second RF signal has a frequency within a range of 100 kHz to 1000 kHz. In one or more embodiments, the second RF signal may have a frequency within a range of 300 kHz to 600 kHz.

In one or more embodiments, as illustrated in FIG. 13, the second RF signal (LF2) has the fourth power level P4 in the first period T1 in each cycle, has the fifth power level P5 in the second period T2 in each cycle, and has the sixth power level P6 in the third period T3 in each cycle. In one or more embodiments, the fourth power level P4 may be a zero power level, and the first period T1 may be in a state in which the second RF signal (LF2) is not supplied to the lower electrode (OFF state). The fifth power level P5 may be larger than the fourth power level P4 which is a zero power level, and may be in a state in which the second RF signal (LF2) is supplied to the lower electrode (ON state) in the second period T2. In one or more embodiments, the fifth power level P5 may be a power level lower than the sixth power level P6.

FIG. 14 is a view illustrating an example of a relationship between the two types of RF signals, and the ion energy (Ei) and the ion flux (Flux) of the ions in the plasma on the substrate W. As illustrated in FIG. 14, the supply of the first RF signal (HF) having a frequency in the MHz band contributes to the variation of the ion flux (Flux) of the ions in the plasma. When the power level of the first RF signal (HF) is raised, the ion flux increases. Meanwhile, the ion energy (Ei) does not vary significantly by the supply of the first RF signal (HF). The supply of the second RF signal (LF2) having a frequency in the kHz band contributes to the variation of the ion energy. Meanwhile, the supply of the second RF signal (LF2) contributes almost nothing to the variation of the ion flux. By combining and using RF signals at two different frequencies, kHz and MHz, the ion energy (Ei) and the ion flux (Flux) on the substrate W can be controlled.

In the first period T1 in the plasma processing, the first RF signal (HF) having the first power level P1 is supplied to the upper electrode, and the second RF signal (LF2) is not supplied to the lower electrode (OFF state), as illustrated in FIG. 13. That is, in the first period T1 in one or more embodiments, since only the first RF signal (HF) is supplied, the ion flux is high and the ion energy is low on the substrate W in the plasma processing space 10s, as illustrated in FIG. 14. As a result, in the first period T1, as in the mode illustrated in FIG. 6, ions and radicals caused from the processing gas are generated in a large amount and diffused, and a part thereof is adsorbed to the mask film MF on the surface of the substrate W, so that the protective film PF is formed.

In the second period T2 in the plasma processing, as illustrated in FIG. 13, the first RF signal (HF) having the second power level P2 is supplied to the upper electrode, and the second RF signal (LF2) having the fifth power level P5 is supplied to the lower electrode. The second power level P2 is lower than the first power level P1. In the second period T2 in one or more embodiments, as illustrated in FIG. 14, the ion flux decreases and the ion energy increases on the substrate W in the plasma processing space 10s as compared with the first period T1. As a result, in the second period T2, as in the mode illustrated in FIG. 6, the generation of ions and radicals is suppressed, and the ions are attracted toward the substrate W. As a result, an etching film EF is etched while the protective film PF is formed. The larger the fifth power level P5 is, the more the formation of the protective film PF is promoted, and the smaller the fifth power level P5 is, the more the etching of the etching film EF is promoted.

In the third period T3 in the plasma processing, as illustrated in FIG. 13, the first RF signal (HF) is not supplied to the upper electrode (OFF state), and the second RF signal (LF2) having the sixth power level P6 is supplied to the lower electrode. In the third period T3 in one or more embodiments, as illustrated in FIG. 14, the ion flux decreases and the ion energy increases on the substrate W in the plasma processing space 10s as compared with the second period T2. As a result, in the third period T3, as in the mode illustrated in FIG. 6, ions are strongly attracted toward the substrate W, and the etching film EF is etched. In this case, the ions are attracted perpendicularly to the substrate W, the ions reach the bottom of the hole of the etching film EF, and the hole diameter of the bottom is secured. Further, the corners of the mask film MF is suppressed from being scraped obliquely or the sidewall of the mask film MF or the etching film EF is suppressed from being bulged.

According to the present exemplary embodiment, the plasma processing apparatus 1 includes the first RF power supply 400 that supplies the first RF signal (HF) having an RF frequency in the MHz band to the upper electrode, and the second RF power supply 401 that supplies the second RF signal (LF2) having an RF frequency in the kHz band to the lower electrode. The first RF signal (HF) has the first power level P1 in the first period T1 in each cycle, the second power level P2 smaller than the first power level P1 in the second period T2 in each cycle, and the third power level P3 having a zero power level in the third period T3 in each cycle. The second RF signal (LF2) has the fourth power level P4 having a zero power level in the first period T1 in each cycle, has the fifth power level P5 in the second period T2 in each cycle, and has the sixth power level P6 larger than the fifth power level P5 in the third period T3 in each cycle. Accordingly, in each of the periods T1 to T3 in each cycle, since the RF signals of the two frequencies of the MHz band and the kHz band can be supplied at the given power level, the ion energy and the ion flux of the generated plasma can be independently controlled. As a result, it is possible to improve the controllability of the plasma generated on the substrate.

### Other Examples of Second Aspect

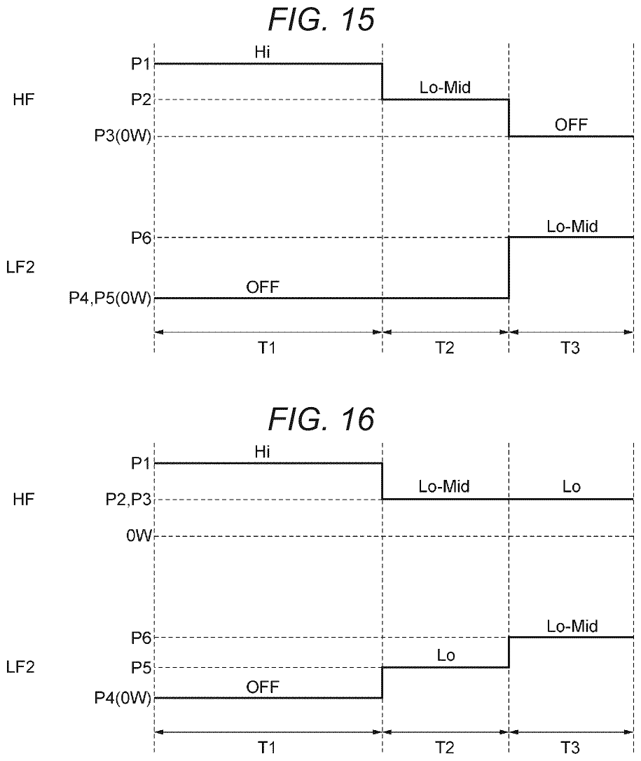

In the second aspect, as illustrated in FIG. 15, in the second period T2 in each cycle, the fifth power level P5 of the second RF signal (LF2) may be a zero power level, and the second RF signal (LF2) may not be supplied to the lower electrode (OFF state) in the second period T2. In this case, in the second period T2, the ion energy of the plasma on the substrate W is low, so that the etching action is relatively weak and the forming action of the protective film by the ions is relatively strong.

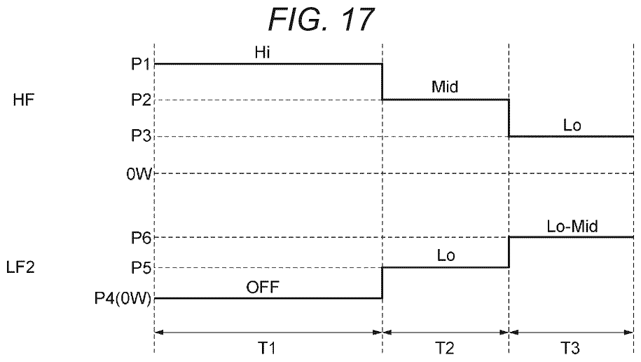

In the second aspect, as illustrated in FIG. 16, in the third period T3 in each cycle, the third power level P3 of the first RF signal (HF) may be larger than a zero power level, and the first RF signal (HF) may be supplied to the upper electrode (ON state). In one or more embodiments, the third power level P3 may be the same as the second power level P2. In this case, in the third period T3, the ion flux of the plasma on the substrate increases, so that the forming action of the protective film is improved.

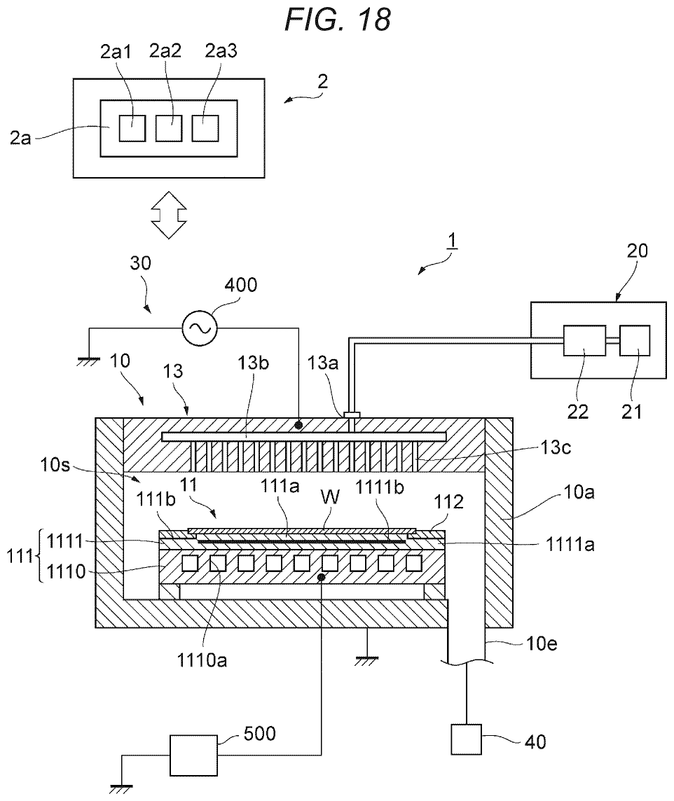

In the second aspect, as illustrated in FIG. 17, in the second period T2 in each cycle, the second power level P2 of the first RF signal (HF) may be smaller than the first power level P1, and the third power level P3 may be smaller than the second power level P2. In one or more embodiments, the third power level P3 is greater than a zero power level. In one or more embodiments, the third power level P3 may have a low power level (Low) as in the mode illustrated in FIG. 16. In this case, in the second period T2, the ion flux of the plasma on the substrate W increases, so that the forming action of the protective film by ions is relatively strong, and the etching action is relatively weak. In the third period T3, the first RF signal (HF) is supplied, so that the ion flux of the plasma on the substrate W increases, and the forming action of the protective film is improved.

In the second aspect, the first period T1, the second period T2, and the third period T3 in each cycle may be consecutively performed, or there may be a period (OFF period) in which the first RF signal (HF) and the second RF signal (LF2) are all stopped, between the first period T1 and the second period T2, and between the second period T2 and the third period T3. The first RF signal (HF) may be supplied to the lower electrode, instead of the upper electrode.

In the second aspect described above, as illustrated in FIG. 18, the plasma processing apparatus 1 may include a voltage pulse generator 500 instead of the second RF power supply 401. That is, instead of the second RF signal (LF2), a voltage pulse signal may be applied to the lower electrode. Other components of the plasma processing apparatus 1 may be similar to those in the above-described aspect.

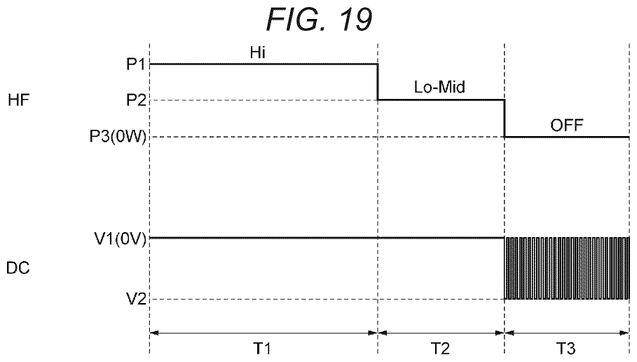

The voltage pulse generator 500 is electrically connected to the lower electrode and configured to generate a voltage pulse signal. The generated voltage pulse signal is applied to the lower electrode. As illustrated in FIG. 19, in one or more embodiments, the voltage pulse signal (DC) has a voltage pulse sequence that has the first voltage level V1 in the first period T1 and the second period T2 in each cycle and has the second voltage level V2 in the third period T3 in each cycle.

In one or more embodiments, the first voltage level VI has a zero voltage level. In one or more embodiments, the voltage pulse sequence has a pulse frequency within a range of 300 kHz to 600 kHz. An absolute value of the second voltage level V2 may be larger than an absolute value of the first voltage level V1. In one or more embodiments, the second voltage level V2 has a negative polarity. The supply and power level of the first RF signal (HF) may be the same as those in the second aspect illustrated in FIG. 13.

In the third period T3 in one or more embodiments, the voltage pulse signal (DC) is applied to the lower electrode, so that the ion energy increases on the substrate W in the plasma processing space 10s as compared with the first period T1 and the second period T2. As a result, in the third period T3, the ions are strongly attracted toward the substrate W, and the etching film EF is etched. In this case, the ions are attracted perpendicularly to the substrate W, the ions reach the bottom of the hole of the etching film EF, and the hole diameter of the bottom is secured. Further, the corners of the mask film MF is suppressed from being scraped obliquely or the sidewall of the mask film MF or the etching film EF is suppressed from being bulged. The present mode in which the voltage pulse signal (DC) is applied by the voltage pulse generator 500 may be applied to all the second aspects shown in FIGS. 15, 16, 17, and the like.

For example, the above embodiment has been described by taking a capacitively-coupled plasma processing apparatus as an example, but the present disclosure is not limited thereto and may be applied to other plasma processing apparatuses. For example, an inductively- coupled plasma processing apparatus may be used instead of the capacitively-coupled plasma processing apparatus. In this case, the inductively-coupled plasma processing apparatus includes an antenna and a lower electrode. The lower electrode is disposed in the substrate support, and the antenna is disposed on an upper portion of or above a chamber. In one or more embodiments or more embodiments, the first RF power supply 200 is electrically connected to the antenna, and the second RF power supply 201 and the third RF power supply 202 are electrically connected to the lower electrode. Instead of the third RF power supply 202, the voltage pulse generator 300 may be applied. In one or more embodiments, the first RF power supply 400 is electrically connected to the antenna, and the second RF power supply 401 is electrically connected to the lower electrode. Instead of the second RF power supply 401, the voltage pulse generator 500 may be applied. In this way, the first RF power supplies 200 and 400 are electrically connected to the upper electrode of the capacitively-coupled plasma processing apparatus or the antenna of the inductively-coupled plasma processing apparatus. That is, the first RF power supplies 200 and 400 are coupled to the plasma processing chamber 10.

In the above-described exemplary embodiments, various modifications may be made to the present plasma processing apparatus without departing from the scope and spirit of the present disclosure. For example, some components in an embodiment may be added to another embodiment within the ordinary creativity range of a person skilled in the art. Some elements in an embodiment may be replaced with corresponding elements in another embodiment. The present disclosure may include, for example, following configurations.

### (Appendix 1)

A plasma processing apparatus including:
a chamber,
a substrate support disposed inside the chamber and including a lower electrode,
an upper electrode disposed above the substrate support,
a first RF power supply configured to supply a first RF signal having a first RF frequency to the upper electrode or the lower electrode, the first RF signal having a first power level in a first period in each cycle, having a second power level in a second period after the first period in each cycle, and having a third power level in a third period after the second period in each cycle, the third power level having a zero power level,
a second RF power supply configured to supply a second RF signal having a second RF frequency to the lower electrode, the second RF signal having a fourth power level in the first period in each cycle, having a fifth power level in the second period in each cycle, and having a sixth power level in the third period in each cycle, the fourth power level and the sixth power level having a zero power level, and
a third RF power supply configured to supply a third RF signal having a third RF frequency to the lower electrode, the third RF signal having a seventh power level in the first period in each cycle, having an eighth power level in the second period in each cycle, and having a ninth power level in the third period in each cycle, the seventh power level and the eighth power level having a zero power level.

### (Appendix 2)

The plasma processing apparatus according to Appendix 1,
in which the first power level is larger than the second power level.

### (Appendix 3)

The plasma processing apparatus according to Appendix 1 or 2,
in which the second power level has a zero power level.

### (Appendix 4)

The plasma processing apparatus according to any one of Appendices 1 to 3, in which the first RF frequency is larger than the second RF frequency, and the second RF frequency is larger than the third RF frequency.

### (Appendix 5)

The plasma processing apparatus according to any one of Appendices 1 to 4, in which the third RF frequency is within a range of 300 kHz to 600 kHz.

### (Appendix 6)

A plasma processing apparatus including:
a chamber,
a substrate support disposed inside the chamber and including a lower electrode,
an upper electrode disposed above the substrate support,
a first RF power supply configured to supply a first RF signal having a first RF frequency to the upper electrode or the lower electrode, the first RF signal having a first power level in a first period in each cycle, having a second power level in a second period after the first period in each cycle, and having a third power level in a third period after the second period in each cycle, the third power level having a zero power level,
a second RF power supply configured to supply a second RF signal having a second RF frequency to the lower electrode, the second RF signal having a fourth power level in the first period in each cycle, having a fifth power level in the second period in each cycle, and having a sixth power level in the third period in each cycle, the fourth power level and the sixth power level having a zero power level, and
a voltage pulse generator configured to apply a voltage pulse signal to the lower electrode, the voltage pulse signal having a voltage pulse sequence that has a first voltage level in the first period and the second period in each cycle and has a second voltage level in the third period in each cycle, an absolute value of the second voltage level being larger than an absolute value of the first voltage level.

### (Appendix 7)

The plasma processing apparatus according to Appendix 6,

in which the first power level is larger than the second power level.
(Appendix 8)

The plasma processing apparatus according to Appendix 6 or 7,
in which the second power level has a zero power level.

### (Appendix 9)

The plasma processing apparatus according to any one of Appendices 6 to 8,
in which the second voltage level has a negative polarity.

### (Appendix 10)

The plasma processing apparatus according to any one of Appendices 6 to 9,
in which the first voltage level has a zero voltage level.

### (Appendix 11)

The plasma processing apparatus according to any one of Appendices 6 to 10,
in which the voltage pulse sequence has a pulse frequency within a range of 300 kHz to 600 kHz.

### (Appendix 12)

A plasma processing apparatus including:
a chamber,
a substrate support disposed inside the chamber and including a lower electrode,
an upper electrode disposed above the substrate support,
a first RF power supply configured to supply a first RF signal having a first RF frequency to the upper electrode or the lower electrode, the first RF frequency having a MHz band, the first RF signal having a first power level in a first period in each cycle, having a second power level in a second period after the first period in each cycle, and having a third power level in a third period after the second period in each cycle, the second power level being smaller than the first power level, the third power level having a zero power level, and
a second RF power supply configured to supply a second RF signal having a second RF frequency to the lower electrode, the second RF frequency having a kHz band, the second RF signal having a fourth power level in the first period in each cycle, having a fifth power level in the second period in each cycle, and having a sixth power level in the third period in each cycle, the fourth power level having a zero power level, the sixth power level being larger than the fifth power level.

### (Appendix 13)

The plasma processing apparatus according to Appendix 12,
in which the second power level has a zero power level.

### (Appendix 14)

The plasma processing apparatus according to Appendix 12 or 13,
in which the second RF frequency is within a range of 300 kHz to 600 kHz.

### (Appendix 15)

A plasma processing apparatus including:
a chamber,
a substrate support disposed inside the chamber and including a lower electrode,
an upper electrode disposed above the substrate support,
an RF power supply configured to supply an RF signal to the upper electrode or the lower electrode, the RF signal having a first power level in a first period in each cycle, having a second power level in a second period after the first period in each cycle, and having a third power level in a third period after the second period in each cycle, the second power level being smaller than the first power level, the third power level having a zero power level, and
a voltage pulse generator configured to apply a voltage pulse signal to the lower electrode, the voltage pulse signal having a voltage pulse sequence that has a first voltage level in the third period in each cycle.

### (Appendix 16)

The plasma processing apparatus according to Appendix 15, in which the voltage pulse signal has a voltage pulse sequence that has a second voltage level in the second period in each cycle, and an absolute value of the first voltage level is larger than an absolute value of the second voltage level.

### (Appendix 17)

A power supply system used in a plasma processing apparatus, the power supply system including:
a first RF generator configured to generate a first RF signal having a first RF frequency, the first RF signal having a first power level in a first period in each cycle, having a second power level in a second period after the first period in each cycle, and having a third power level in a third period after the second period in each cycle, the third power level having a zero power level,
a second RF generator configured to generate a second RF signal having a second RF frequency, the second RF signal having a fourth power level in the first period in each cycle, having a fifth power level in the second period in each cycle, and having a sixth power level in the third period in each cycle, the fourth power level and the sixth power level having a zero power level, and
a third RF generator configured to generate a third RF signal having a third RF frequency, the third RF signal having a seventh power level in the first period in each cycle, having an eighth power level in the second period in each cycle, and having a ninth power level in the third period in each cycle, the seventh power level and the eighth power level having a zero power level.

### (Appendix 18)

A power supply system used in a plasma processing apparatus, the power supply system including:
a first RF generator configured to generate a first RF signal having a first RF frequency, the first RF signal having a first power level in a first period in each cycle, having a second power level in a second period after the first period in each cycle, and having a third power level in a third period after the second period in each cycle, the third power level having a zero power level,
a second RF generator configured to generate a second RF signal having a second RF frequency, the second RF signal having a fourth power level in the first period in each cycle, having a fifth power level in the second period in each cycle, and having a sixth power level in the third period in each cycle, the fourth power level and the sixth power level having a zero power level, and
a voltage pulse generator configured to generate a voltage pulse signal, the voltage pulse signal having a voltage pulse sequence that has a first voltage level in the first period and the second period in each cycle and has a second voltage level in the third period in each cycle, an absolute value of the second voltage level being larger than an absolute value of the first voltage level.

### (Appendix 19)

A power supply system used in a plasma processing apparatus, the power supply system including:
a first RF generator configured to generate a first RF signal having a first RF frequency, the first RF frequency having a MHz band, the first RF signal having a first power level in a first period in each cycle, having a second power level in a second period after the first period in each cycle, and having a third power level in a third period after the second period in each cycle, the second power level being smaller than the first power level, the third power level having a zero power level, and
a second RF generator configured to generate a second RF signal having a second RF frequency, the second RF frequency having a kHz band, the second RF signal having a fourth power level in the first period in each cycle, having a fifth power level in the second period in each cycle, and having a sixth power level in the third period in each cycle, the fourth power level having a zero power level, the sixth power level being larger than the fifth power level.

### (Appendix 20)

A power supply system used in a plasma processing apparatus, the power supply system including:
an RF generator configured to generate an RF signal, the RF signal having a first power level in a first period in each cycle, having a second power level in a second period after the first period in each cycle, and having a third power level in a third period after the second period in each cycle, the second power level being smaller than the first power level, the third power level having a zero power level, and
a voltage pulse generator configured to generate a voltage pulse signal, the voltage pulse signal having a voltage pulse sequence that has a first voltage level in the third period in each cycle.

1. A plasma processing apparatus comprising:
a chamber;
a substrate support disposed in the chamber and including a lower electrode;
an upper electrode disposed above the substrate support;
a first RF power supply configured to supply a first RF signal having a first RF frequency to the upper electrode or the lower electrode, the first RF signal having a first power level in a first period in each cycle, having a second power level in a second period after the first period in each cycle, and having a third power level in a third period after the second period in each cycle, the third power level having a zero power level;
a second RF power supply configured to supply a second RF signal having a second RF frequency to the lower electrode, the second RF signal having a fourth power level in the first period in each cycle, having a fifth power level in the second period in each cycle, and having a sixth power level in the third period in each cycle, the fourth power level and the sixth power level having a zero power level; and
a third RF power supply configured to supply a third RF signal having a third RF frequency to the lower electrode, the third RF signal having a seventh power level in the first period in each cycle, having an eighth power level in the second period in each cycle, and having a ninth power level in the third period in each cycle, the seventh power level and the eighth power level having a zero power level.

2. The plasma processing apparatus according to claim 1,
wherein the first power level is greater than the second power level.

3. The plasma processing apparatus according to claim 2,
wherein the second power level has a zero power level.

4. The plasma processing apparatus according to claim 1,
wherein the first RF frequency is greater than the second RF frequency, and
the second RF frequency is greater than the third RF frequency.

5. The plasma processing apparatus according to claim 4,
wherein the third RF frequency is within a range of 300 kHz to 600 KHz.

6. A plasma processing apparatus comprising:
a chamber;
a substrate support disposed in the chamber and including a lower electrode,
an upper electrode disposed above the substrate support;
a first RF power supply configured to supply a first RF signal having a first RF frequency to the upper electrode or the lower electrode, the first RF signal having a first power level in a first period in each cycle, having a second power level in a second period after the first period in each cycle, and having a third power level in a third period after the second period in each cycle, the third power level having a zero power level;
a second RF power supply configured to supply a second RF signal having a second RF frequency to the lower electrode, the second RF signal having a fourth power level in the first period in each cycle, having a fifth power level in the second period in each cycle, and having a sixth power level in the third period in each cycle, the fourth power level and the sixth power level having a zero power level; and
a voltage pulse generator configured to apply a voltage pulse signal to the lower electrode, the voltage pulse signal having a voltage pulse sequence that has a first voltage level in the first period and the second period in each cycle and has a second voltage level in the third period in each cycle, an absolute value of the second voltage level being greater than an absolute value of the first voltage level.

7. The plasma processing apparatus according to claim 6,
wherein the first power level is greater than the second power level.

8. The plasma processing apparatus according to claim 7,
wherein the second power level has a zero power level.

9. The plasma processing apparatus according to claim 6,
wherein the second voltage level has a negative polarity.

10. The plasma processing apparatus according to claim 9,
wherein the first voltage level has a zero voltage level.

11. The plasma processing apparatus according to claim 6,
wherein the voltage pulse sequence has a pulse frequency within a range of 300 kHz to 600 kHz.

12. A power supply system for use in a plasma processing apparatus, the power supply system comprising:
a first RF generator configured to generate a first RF signal having a first RF frequency, the first RF signal having a first power level in a first period in each cycle, having a second power level in a second period after the first period in each cycle, and having a third power level in a third period after the second period in each cycle, the third power level having a zero power level;
a second RF generator configured to generate a second RF signal having a second RF frequency, the second RF signal having a fourth power level in the first period in each cycle, having a fifth power level in the second period in each cycle, and having a sixth power level in the third period in each cycle, the fourth power level and the sixth power level having a zero power level; and
a third RF generator configured to generate a third RF signal having a third RF frequency, the third RF signal having a seventh power level in the first period in each cycle, having an eighth power level in the second period in each cycle, and having a ninth power level in the third period in each cycle, the seventh power level and the eighth power level having a zero power level.

13. The power supply system according to claim 12,
wherein the first power level is greater than the second power level.

14. The power supply system according to claim 13,
wherein the second power level has a zero power level.

15. The power supply system according to claim 12,
wherein the first RF frequency is greater than the second RF frequency, and
the second RF frequency is greater than the third RF frequency.

16. The power supply system according to claim 15,
wherein the third RF frequency is within a range of 300 kHz to 600 kHz.
